(19) United States
(12) Patent Application Publication
(10) Pub. No.: US 2026/0279716 A1
(43) Pub. Date: Sep. 17, 2026

(54) FOCUSED ION BEAM SYSTEM WITH SINGLE OPTICAL COLUMN

(71) Applicant: ALES TECH INC., Kaohsiung City (TW)

(72) Inventors: Chun-Yueh Lin, Keelung City (TW); Wei-Tse Chang, Taoyuan City (TW); Wei-Chiao Lai, Yunlin County (TW); Zong-Yu Yang, Kinmen County (TW); Ching-Yu Hsiao, Taoyuan City (TW); Wun-Cin Huang, Taipei City (TW)

(73) Assignee: ALES TECH INC., Kaohsiung City (TW)

(21) Appl. No.: 19/177,437

(22) Filed: Apr. 11, 2025

(30) Foreign Application Priority Data
Jan. 23, 2025 (TW) 114103229

(51) Int. Cl. H01J 37/05; H01J 37/30

(52) U.S. Cl. CPC H01J 37/05; H01J 37/3005; H01J 37/3007

(57) ABSTRACT

The focused ion beam system comprises a vacuum chamber, an emitter, a gas pressure control device, an optical column, a voltage control module, and a signal control module. The emitter, the optical column, and a sample are positioned in the vacuum chamber. The gas pressure control device stores gas and is connected to the vacuum chamber. The voltage control module is electrically connected to the emitter and the optical column, and generates an extraction voltage to the emitter and a voltage to the optical column. The signal control module is connected to the gas pressure control device and the voltage control module and generates a gas import signal to introduce the gas into the vacuum chamber. The signal control module adjusts an output voltage and the extraction voltage to generate a heavy ion beam and a light ion beam.

### CROSS-REFERENCE TO RELATED APPLICATIONS

This application claims the priority benefit of TW application serial No. 114103229 filed on Jan. 23, 2025, the entirety of which is hereby incorporated by reference herein and made a part of the specification.

### BACKGROUND OF THE INVENTION

### 1. Field of the Invention

The invention discloses a focused ion beam system, particularly to a system with a single column.

### 2. Description of the Related Art

Refer to FIG. 2. FIG. 2 is a conventional schematic diagram of a dual-beam focused ion beam system. The current focused ion beam (FIB) system plays an indispensable role in a domain of semiconductor failure analysis and circuit editing. Presently, a commonly used dual-beam focused ion beam system (Dual-Beam FIB; DB-FIB) 2 consists of two optical columns 21, 22. One column 21 is used to generate a heavy ion beam such as a gallium ion beam or a xenon ion beam for processing a sample S. The other column 22 is used to generate an electron beam or a light ion beam for microscopy imaging of the sample S. However, in the dual-beam focused ion beam system 2, or even in a focused ion beam system utilizing three columns, at least two independently arranged optical systems are required for processing and microscopy imaging the sample S. Consequently, for the dual-beam focused ion beam system 2, the cost of the equipment is expensive, the structure of the system is complex, and the procedure of the manipulation is complicated.

In the past, single column systems have been developed to generate both a heavy ion beam for processing the sample S and an electron beam for imaging, aiming to address the aforementioned problems. However, the single column systems failed to be accomplished due to the complexity of the mechanical-operation switch or the instability of the emitter structure. In detail, the single column focused ion beam and electron beam system uses a liquid metal ion source. The liquid metal flows toward the tip end of the emitter upon heating and the ion beam is emitted after a high voltage is applied to the emitter. When the liquid metal cools, the liquid metal forms a base for electron beam emission at the tip end of the emitter. After emitting an ion beam, the liquid metal at the tip end of the emitter decreases. Subsequently, the emitter needs to be heated to replenish the liquid metal at the tip end. However, due to the inability of the liquid metal to maintain a fixed shape, the position and the size of the liquid metal at the tip end of the emitter vary after each heating and cooling cycle, making the liquid metal impossible to form a stable base for the electron beam emission.

Accordingly, how to provide a focused ion beam system with a single column is an urgent subject to tackle.

### SUMMARY

In view of this, the invention discloses a focused ion beam system with a single optical column, comprising a vacuum chamber, an emitter, a gas pressure control device, an optical column, a voltage control module and a signal control module. The vacuum chamber has an inner space. The emitter, the optical column and the sample are all positioned within the inner space of the vacuum chamber. The gas pressure control device stores at least one gas and is connected to a wall surface of the vacuum chamber. The voltage control module is electrically connected to the emitter and the optical column, generates an extraction voltage to the emitter, and generates a voltage to the optical column. The signal control module is connected to the gas pressure control device and the voltage control module and generates a gas import signal to the gas pressure control device so that the gas pressure control device introduces at least one gas into the inner space of the vacuum chamber. The signal control module adjusts the output voltage from the voltage control module to the optical column and adjusts the extraction voltage supplied to the emitter. This enables the emitter to generate a heavy ion beam for processing the sample and a light ion beam for imaging the sample by at least one gas. The heavy ion beam for processing the sample is generated by a first gas in the at least one gas. The light ion beam for imaging the sample is generated by a second gas in the at least one gas. The molecular weight of the first gas is greater than the molecular weight of the second gas. The signal control module adjusts the extraction voltage according to the molecules of the first gas and the second gas.

As mentioned above, when the signal control module generates the gas import signal to the gas pressure control device, the gas pressure control device introduces the first gas into the inner space of the vacuum chamber. The signal control module adjusts the extraction voltage from the voltage control module so that the emitter emits an ion beam of the first gas. The signal control module adjusts the output voltage supplied to the optical column via the voltage control module, allowing the focusing lens module to control the beam spot size on the sample. The scanning deflection module directs the ion beam across the sample surface for scanning and processing. The signal detector captures signals generated by the interaction between the ion beam and the sample, transmitting the signal to the signal control module for imaging. After that, the signal control module generates a gas import signal to the gas pressure control device so that the gas pressure control device introduces the second gas into the inner space of the vacuum chamber. The signal control module adjusts the extraction voltage from the voltage control module so that the emitter emits the ion beam of the second gas. The signal control module adjusts the output voltage supplied to the optical column via the voltage control module, allowing the focusing lens module to control the beam spot size on the sample. The scanning deflection module directs the ion beam across the sample surface for scanning and imaging. The signal detector captures signals generated by the interaction between the ion beam and the sample, and transmits the signals to the signal control module for imaging. The signal control module stops the gas from being introduced into the vacuum chamber by closing the valve. After the pressure of the vacuum chamber returns to an ultra-high vacuum state, the signal control module generates an electron extraction negative voltage to the voltage control module so that the emitter emits an electron beam. The signal control module controls the voltage control module to adjust the output voltage to the optical column. The focusing lens module adjusts the electron beam spot size on the sample. The scanning deflection module controls the electron beam scanning on the surface of the sample. The signal detector detects signals generated by the interaction between the electron beam and the sample and transmits the signals to the signal control module for imaging.

As mentioned above, when the signal control module generates the gas import signal to the gas pressure control device, multiple gases can be simultaneously introduced into the vacuum chamber. Various molecules have distinct ionization energies. According to the characteristic, the desired ion beam can be selected by a specific ionization energy. Additionally, a mass separator can be added in the optical column to select the desired ion beam. Alternatively, after introducing one gas and completing the designated task, the signal control module closes the valve and stops the gas from being introduced into the vacuum chamber. After the pressure around the emitter returns to the ultra-high vacuum, the signal control module generates the gas import signal to the gas pressure control device to introduce another gas to process another procedure. As mentioned above, the focused ion beam system with the single optical column generates multiple particle beams by regulating the types of gas in the vacuum chamber and applying different ionization voltages. Therefore, the invention can be applied to various needs, including multifunctional processing, high-precision machining, high-resolution imaging, composition analyses and so on. The invention enables the generation and applications of different charged particle beams. In addition, by the single optical column, the invention can both significantly reduce the cost of the equipment and the complexity of the system and further improve the ease of operation.

### BRIEF DESCRIPTION OF THE DRAWINGS

FIG. 1A is the block diagram of the focused ion beam system with the single column;

FIG. 1B is the schematic diagram for the emitter, the optical column and the sample positioned in the vacuum chamber;

FIG. 1C is the enlarged schematic of the tip end of the emitter;

FIG. 1D is the schematic diagram showing that the vacuum chamber can be divided into an optical column vacuum chamber and a sample vacuum chamber;

FIG. 1E is a schematic diagram of the gas flow path between the gas pressure control device and the vacuum chamber; and

FIG. 2 is a schematic diagram of a conventional dual-beam focused ion beam system.

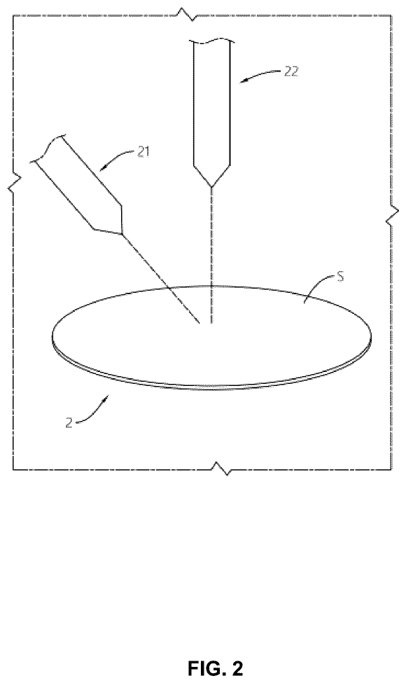

### DETAILED DESCRIPTION OF THE INVENTION

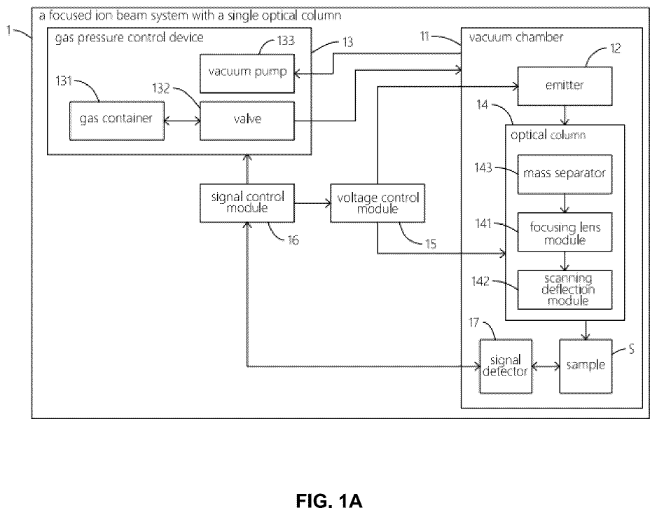

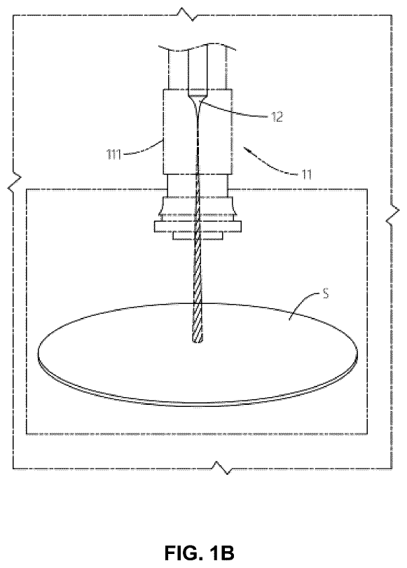

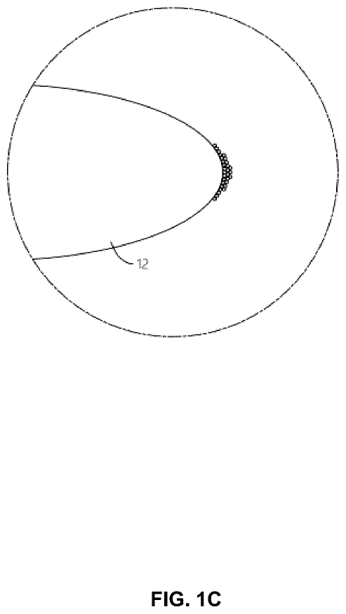

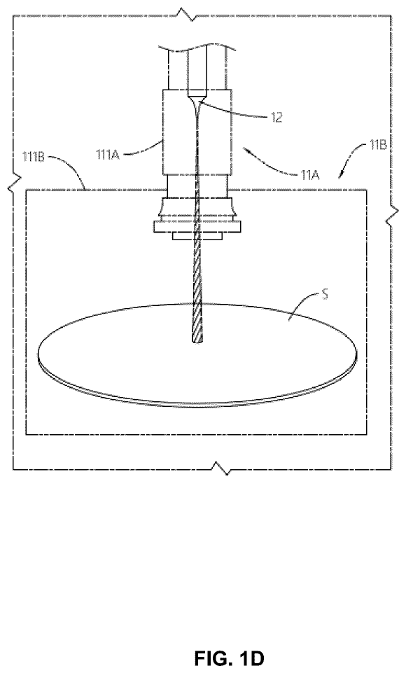

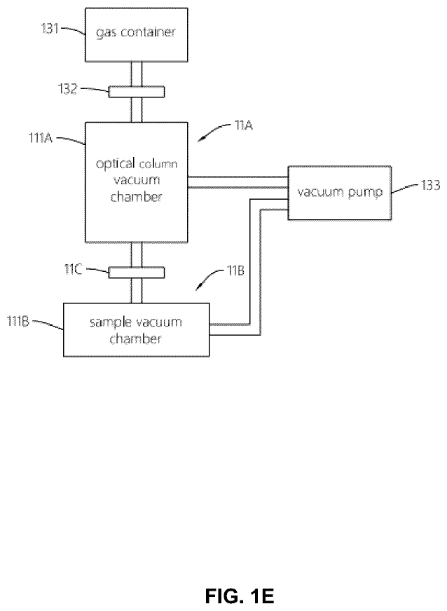

Refer to FIG. 1A to FIG. 1C. FIG. 1A is the block diagram of the focused ion beam system with the single optical column. FIG. 1B is the schematic diagram for the emitter, the optical column and the sample positioned in the vacuum chamber. FIG. 1C is the enlarged schematic of the tip end of the emitter. The focused ion beam system with the single optical column 1 comprises a vacuum chamber 11, an emitter 12, a gas pressure control device 13, an optical column 14, a voltage control module 15, and a signal control module 16. In an embodiment, the voltage control module 15 and the signal control module 16 can be integrated in a single voltage signal control device. The vacuum chamber 11 has an inner space. The emitter 12, the optical column 14 and the sample S are positioned in the inner space of the vacuum chamber 11. The gas pressure control device 13 stores at least one gas and is connected to the wall surface 111 of the vacuum chamber 11. The voltage control module 15 is electrically connected to the emitter 12 and the optical column 14. The voltage control module 15 generates an extraction voltage to the emitter 12 and generates a voltage to the optical column 14. The signal control module 16 is connected to the gas pressure control device 13 and the voltage control module 15. The signal control module 16 generates a gas import signal to the gas pressure control device 13 so that the gas pressure control device 13 introduces at least one gas into the inner space of the vacuum chamber 11. The signal control module 16 adjusts the output voltage from the voltage control module 15 to the optical column 14 and adjusts the extraction voltage from the voltage control module 15 to the emitter 12 so that the emitter 12 generates the heavy ion beam for processing the sample S and the light ion beam for imaging the sample S via the at least one gas. The heavy ion beam for processing the sample S is generated by the first gas in the at least one gas. The signal control module 16 adjusts the extraction voltage according to the molecule of the first gas. The light ion beam for imaging the sample S is generated by the second gas in the at least one gas. The signal control module 16 adjusts the extraction voltage according to the molecule of the second gas. The molecular weight of the first gas is greater than the molecular weight of the second gas.

In an embodiment of the present invention, the molecular weight of the first gas is greater than twenty-one. The first gas comprises xenon, krypton, oxygen, nitrogen, and argon. The molecular weight of the second gas is smaller than twenty-one. The second gas comprises hydrogen, neon, and helium.

The focused ion beam system with the single optical column 1 further comprises a signal detector 17. The signal detector 17 is connected to the signal control module 16. The signal detector 17 captures the signal generated by the interaction between the electron beam and the sample S and the signal generated by interaction between the ion beam and the sample S. The signal detector 17 transmits the signal to the signal control module 16 to image the sample S.

The optical column 14 comprises a focusing lens module 141, a scanning deflection module 142, and a mass separator 143. The optical column 14 is positioned along the propagation path of the ion beam and the electron beam between the emitter 12 and the sample S. The optical column 14 is utilized to control the ion beam and the electron beam. The focusing lens module 141 adjusts the beam spot size on the surface of the sample S. When the focused ion beam system with the single optical column generates the heavy ion beam to process the sample S, the scanning deflection module 142 directs the ion beam across the surface of the sample S for scanning and processing. When the system generates the light ion beam and the electron beam to image the sample S, the scanning deflection module 142 directs the ion beam and the electron beam across the surface of the sample S for scanning and imaging. When the signal control module 16 generates the gas import signal to the gas pressure control device 13, multiple gases can be simultaneously introduced into the vacuum chamber 11. The multiple gases comprise the first gas and the second gas. The voltage control module 15 applies the appropriate extraction voltage to select the desired ion beam based on the characteristic that different molecules have different ionization energies. Alternatively, the mass separator 143 selects the desired ion beam according to the charge-to-mass ratios. In another embodiment, after introducing one gas and completing the designated task, the signal control module 16 closes the valve 132 and stops the gas from being introduced into the vacuum chamber 11. After the pressure around the emitter returns to the ultra-high vacuum, the signal control module 16 generates the gas import signal to the gas pressure control device 13 to introduce another gas to process another procedure. The mass separator 143 allows ions with a specific charge-to-mass ratio to pass through the mass separator 143 without deflection, while ions with different charge-to-mass ratios are deflected and blocked by the mass separator 143. Therefore, the mass separator 143 enables further selection of the desired ions.

The gas pressure control device 13 comprises a gas container 131, a valve 132, and a vacuum pump 133. The vacuum pump 133 is connected to the wall surface 111 of the vacuum chamber 11 and the signal control module 16. The valve 132 is connected to the wall surface 111 of the vacuum chamber 11 and the signal control module 16. The valve 132 is used to adjust the gas introduced into the vacuum chamber 11 according to the gas import signal generated by the signal control module 16 and stops introducing the gas into the vacuum chamber 11 according to the gas pumping signal generated by the signal control module 16. The gas pumping signal generated by the signal control module 16 is transmitted to the vacuum pump 133. The vacuum pump 133 connected to the vacuum chamber 11 pumps the gas in the vacuum chamber 11 according to the gas pumping signal. It should be noted that the sequence for generating the heavy ion beam, the light ion beam, and the electron beam is not limited in the embodiment of the present invention. In fact, the heavy ion beam, the light ion beam, and the electron beam can be generated according to the user demand. For instance, when the user desires to process and image the sample S, the first gas and the second gas can be simultaneously introduced into the vacuum chamber 11 or introduced into the vacuum chamber 11 one after another. The heavy ion beam and the light ion beam can be generated according to the different ionization energies of different molecules. Alternatively, the mass separator 143 can be positioned in the optical column 14 to select the ion beam with a specific charge-to-mass ratio. Alternatively, after the gas for processing the sample S is introduced into the vacuum chamber 11 and the vacuum pump 133 pumps all the gases in the vacuum chamber 11, the electron beam for imaging the sample S can be generated.

In an embodiment of the present invention, the ion beam is generated by introducing a single type of gas into the vacuum chamber 11. Alternatively, different ion beams are generated by introducing multiple mixed gases into the vacuum chamber 11. Furthermore, the electron beam is generated by pumping all gases in the vacuum chamber 11. In addition, the signal control module 16 generates a first gas import signal to the gas pressure control device 13 to introduce the first gas into the inner space of the vacuum chamber 11. The voltage control module 15 applies the extraction voltage on the emitter 12 according to the ionization energy of the introduced first gas. The extraction voltage generates an ionization field near the tip end of the emitter. The ionization field attracts the gas absorbed on the shank of the emitter 12 to the tip end surface. The ionization field is able to ionize the gas attracted to the tip end surface of the emitter 12 to generate the first gas ion beam. Take xenon as an example: when xenon is introduced into the inner space of the vacuum chamber 11, the voltage control module 15 applies the positive extraction voltage to the emitter 12. When the applied electric field reaches the ionization energy required to ionize xenon absorbed on the tip end surface of the emitter 12, a xenon ion beam is generated. The applied electric field further attracts xenon absorbed on the shank of the emitter 12 to the tip end surface to generate the xenon ion beam continuously.

When the signal control module 16 generates the gas pumping signal, the signal control module closes the valve 132, stopping the introduction of the first gas into the vacuum chamber 11. After the vacuum pump 133 pumps out the first gas in the vacuum chamber 11, the signal control module 16 further generates the second gas import signal to the gas pressure control device 13 so that the gas pressure control device 13 introduces the second gas into the inner space of the vacuum chamber 11. The voltage control module 15 applies the extraction voltage to the emitter 12 according to the ionization energy of the second gas to generate the second gas ion beam.

When the signal control module 16 generates the gas pumping signal, the signal control module closes the valve 132, preventing the gas from being introduced into the vacuum chamber 11. After the vacuum pump 133 pumps out the gas in the vacuum chamber 11 and the pressure around the emitter 12 returns to the ultra-high vacuum, the signal control module 16 generates an electron extraction negative voltage to the voltage control module 15, causing the emitter 12 to emit the electron beam.

Different ion beams disclosed in above embodiments provide different functions according to the light gas and the heavy gas. The light and heavy gases are distinguished based on their molecular weights. Take xenon and helium as an example: xenon is heavy gas, while helium, in contrast, is light gas. Hence, the xenon ion beam generated from xenon gas is suitable for processing the sample S. The helium ion beam generated from helium gas causes minimal damage to the sample S, making it suitable for high-resolution imaging of the sample S.

Furthermore, when mixed gases with more than two gases are simultaneously introduced into the vacuum chamber 11, the desired ion beam can be selected by the applied extraction voltage based on the characteristic that different molecules have different ionization energies. To prevent interference between the different ion beams generated by the different gases due to the close ionization energies of the different gases, a mass separator is positioned in the optical column to select the ion beam. Accordingly, ion beams generated from different gases can be flexibly applied to various operational environments.

Besides, the gases introduced into the vacuum chamber 11 are categorized for processing, imaging, and mass spectrometric analyzing the sample S according to the ionization energies, the molecular properties, and the reactivity. That is, the focused ion beam system with a single optical column of the invention mixes different gases in the inner space of the vacuum chamber 11 and adjusts the extraction voltages corresponding to the gases so that the heavy ion beam for processing the sample S, the light ion beam and the electron beam for imaging the sample S and the ion beam for mass spectrometric analyzing the sample S can be generated. For example, when the voltage generated by the voltage control module 15 is applied to the emitter 12 so that the voltage on the tip end of the emitter reaches the ionization voltage of the first gas, the first gas is ionized from the tip end surface of the emitter 12 to generate the first gas ion beam. When the voltage generated by the voltage control module 15 is applied to the emitter 12 so that the voltage on the tip end of the emitter reaches the ionization voltage of the second gas, the second gas is ionized from the tip end surface of the emitter 12 to generate the second gas ion beam. Moreover, the signal control module 16 further adjusts the extraction voltage generated by the voltage control module 15 and applies it to the emitter 12 so that the emitter 12 generates the third gas ion beam for mass spectrometric analyzing the sample S. The third gas ion beam comprises the ion beam generated by reactive gas or a molecular cluster.

In an embodiment of the present invention, the tip end of the emitter 12 is a faceting structure. The material of the emitter comprises at least one of tungsten, iridium, molybdenum, palladium, platinum, rhodium, and gold. In an embodiment, the material of the emitter comprises a composite metal consisting of at least one of tungsten, iridium, molybdenum, palladium, platinum, rhodium, and gold. In an embodiment, the material of the emitter is tungsten and at least one of iridium, molybdenum, palladium, platinum, rhodium, and gold is electroplated on the surface of the emitter.

Refer to FIG. 1D and FIG. 1E. FIG. 1D is the schematic diagram showing that the vacuum chamber can be divided into the optical column vacuum chamber and the sample vacuum chamber. FIG. 1E is the schematic diagram of the gas flow path between the gas pressure control device and the vacuum chamber. In an embodiment, the vacuum chamber 11 comprises an optical column vacuum chamber 11A and a sample vacuum chamber 11B. The optical column vacuum chamber 11A is used to accommodate the emitter 12 and the optical column 14. The sample vacuum chamber 11B is used to accommodate the sample S. The optical column vacuum chamber 11A has a first wall surface 111A and a first inner space. The sample vacuum chamber 11B has a second wall surface 111B and a second inner space. Both the first wall surface 111A and the second wall surface 111B form the whole wall surface 111 of the vacuum chamber 11. Furthermore, both the first inner space of the optical column vacuum chamber 11A and the second inner space of the sample vacuum chamber 11B form the whole inner space of the vacuum chamber 11.

The optical column vacuum chamber 11A is connected to the sample vacuum chamber 11B. The optical column vacuum chamber 11A has a vacuum valve 11C. When the vacuum valve 11C is closed, the optical column vacuum chamber 11A is disconnected from the sample vacuum chamber 11B. In addition, both the first wall surface 111A of the optical column vacuum chamber 11A and the second wall surface 111B of the sample vacuum chamber 11B are connected to the vacuum pump 133 so that both the gas in the optical column vacuum chamber 11A and the gas in the sample vacuum chamber 11B can be simultaneously pumped by the vacuum pump 133 to maintain the vacuum pressure. The gas container 131 is connected to the first wall surface 111A of the optical column vacuum chamber 11A via the valve 132 so that the gas is delivered to the emitter 12 to generate the gas ion beam.

When the vacuum valve 11C is closed, the sample vacuum chamber 11B is isolated from the gas container 131, preventing gas delivery. In the meanwhile, the vacuum pump 133 pumps out the gas in the sample vacuum chamber 11B to improve the vacuum quality. Alternatively, when the vacuum valve 11C is closed, the sample vacuum chamber 11B can be vented, allowing the user to replace the sample S in the sample vacuum chamber 11B. At the same time, the vacuum pump 133 constantly pumps out the gas in the optical column vacuum chamber 11A to maintain the vacuum quality of the optical column vacuum chamber 11A. In an embodiment, the vacuum valve 11C can be a manual valve or an electrically controlled valve adjusted by the signal control module 16.

In summary, the focused ion beam system with the single optical column utilizes a robust and stable structure of the emitter to fix the position of the emitter to generate a stable charged particle beam. Accordingly, the stability and the life time of the ion source and the electron source are improved and prolonged. Furthermore, the focused ion beam system with the single optical column can generate a variety of charged particle beams using only a single optical column by adjusting the gas type in the vacuum chamber and applying the corresponding ionization voltages. Therefore, the invention can be applied to various needs, including multifunctional processing, high-precision machining, high-resolution imaging, composition analyses and so on. The invention enables the generation and applications of different charged particle beams. In addition, by the single optical column, the invention can both significantly reduce the cost of the equipment and the complexity of the system and further improve the ease of operation.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A focused ion beam system with a single optical column, comprising:
a vacuum chamber, having an inner space;
an emitter, positioned in the inner space of the vacuum chamber; and
a gas pressure control device, storing at least one gas and connected to a wall surface of the vacuum chamber;
an optical column, positioned between the emitter and a sample;
a voltage control module, electrically connected to the emitter and the optical column, generating an extraction voltage to the emitter, and generating a voltage to the optical column; and
a signal control module, connected to the gas pressure control device and the voltage control module, the signal control module generating a gas import signal to the gas pressure control device so that the gas pressure control device introduces the at least one gas into the inner space of the vacuum chamber;
wherein the signal control module adjusts the voltage from the voltage control module to the optical column, and adjusts the extraction voltage from the voltage control module to the emitter so that the emitter generates a heavy ion beam for processing or analyzing the sample, and a light ion beam for imaging the sample by the at least one gas;
wherein the heavy ion beam for processing or analyzing the sample is generated by a first gas in the at least one gas and the light ion beam for imaging the sample is generated by a second gas in the at least one gas;
wherein the molecular weight of the first gas is greater than the molecular weight of the second gas and the signal control module adjusts the extraction voltage according to the molecular properties of the first gas and the molecular properties of the second gas.

2. The focused ion beam system with the single optical column as claimed in claim 1, wherein the first gas comprises xenon, krypton, oxygen, nitrogen, and argon and the second gas comprises hydrogen, neon, and helium.

3. The focused ion beam system with the single optical column as claimed in claim 1, wherein the molecular weight of the first gas is greater than 21, and the molecular weight of the second gas is smaller than 21.

4. The focused ion beam system with the single optical column as claimed in claim 1, wherein the at least one gas comprises mixed gases of the first gas and the second gas and the signal control module adjusts the extraction voltage from the voltage control module to the emitter according to the molecular properties of the first gas and the molecular properties the second gas.

5. The focused ion beam system with the single optical column as claimed in claim 1, wherein when the signal control module generates the gas import signal to the gas pressure control device, the gas pressure control device introduces the first gas into the inner space of the vacuum chamber, the signal control module further generates a gas pumping control signal to the gas pressure control device to pump the first gas, the signal control module generates the gas import signal to the gas pressure control device so that the gas pressure control device introduces the second gas into the inner space of the vacuum chamber.

6. The focused ion beam system with the single optical column as claimed in claim 1, wherein the optical column comprises a mass separator for selecting a gas ion beam that includes the heavy ion beam and the light ion beam.

7. The focused ion beam system with the single optical column as claimed in claim 1, wherein the signal control module further generates a gas pumping signal to the gas pressure control device to pump out the at least one gas and the signal control module adjusts the extraction voltage from the voltage control module to the emitter as a negative voltage so that the emitter generates an electron beam for imaging the sample.

8. The focused ion beam system with the single optical column as claimed in claim 1, wherein a tip end of the emitter is a faceting structure.

9. The focused ion beam system with the single optical column as claimed in claim 1, wherein a material of the emitter comprises at least one of tungsten, iridium, molybdenum, palladium, platinum, rhodium, and gold.

10. The focused ion beam system with the single optical column as claimed in claim 1, wherein the optical column comprises:
a focusing lens module, adjusting the beam spot size on the sample; and
a scanning deflection module, directing the ion beam across the sample for scanning and shifting.

11. The focused ion beam system with the single optical column as claimed in claim 1, further comprising a signal detector, connected to the signal control module, capturing a signal generated by the interaction between the ion beam and the sample, transmitting the signal to the signal control module for imaging.
